(19) United States
(12) Patent Application Publication
(10) Pub. No.: US 2010/0227447 A1
(43) Pub. Date: Sep. 9, 2010

(54) METHOD OF MANUFACTURING FLASH MEMORY DEVICE

(75) Inventors: Hung-Wei Chen, Chu-Pei City (TW); Yider Wu, Chu-Pei City (TW)

Correspondence Address: SCHMEISER, OLSEN & WATTS, 22 CENTURY HILL DRIVE, SUITE 302, LATHAM, NY, 12110, US

(73) Assignee: EON SILICON SOLUTIONS INC., Chu-Pei City (TW)

(21) Appl. No.: 12/399,124

(22) Filed: Mar. 6, 2009

(51) Int. Cl. H01L 21/8234

(52) U.S. Cl. 438/302; 257/E21.619

(57) ABSTRACT

A flash memory device manufacturing process includes the steps of providing a semiconductor substrate; forming two gate structures on the substrate; performing an ion implantation process to form two first source regions in the substrate at two lateral outer sides of the two gate structures; performing a further ion implantation process to form a first drain region in the substrate between the two gate structures; performing a pocket implantation process between the gate structures to form two doped regions in the substrate at two opposite sides of the first drain region; forming two facing L-shaped spacer walls between the two gate structures above the first drain region; performing an ion implantation process to form a second drain region beneath the first drain region, both of which having a steep junction profile compared to the first source regions; and forming a barrier plug above the first drain region.

### FIELD OF THE INVENTION

The present invention relates to a method of manufacturing a memory device, and more particularly to a method of manufacturing a flash memory device.

### BACKGROUND OF THE INVENTION

With the progress in semiconductor process technique, the process technique for memory devices also moves into the era of nanometer technology. The reduction of device dimensions increases not only the density of integrated circuit (IC), but also the current driving ability of the device. However, the movement of the memory devices into the nanometer era also brings the problems of short channel effects (SCE) and gate leakage current. As a result, it becomes more difficult to enhance the memory device performance by reducing the channel length and gate oxide layer thickness of the memory device.

For example, a lightly doped drain (LDD) enables the device to have an increased breakdown voltage, improved critical voltage property, and reduced hot carrier effect. While the lightly doped drain reduces the high electric field at the drain junction and effectively upgrades the reliability of the device, the punch-through phenomena becomes worse when the device dimensions are gradually reduced. The pocket implantation is brought forward to improve the short channel effects as the result of the punch-through phenomena. While the pocket implantation improves the short channel effects of the device, the phenomena of drain current (IDSAT) degradation will occur due to high channel doping.

It is therefore very important to improve the doping degree or ratio and the junction profile at the source, the drain, and the pocket ion implantation region, so as to improve the above-mentioned problems and to obtain a balance point for the memory device to work at the highest efficiency.

### SUMMARY OF THE INVENTION

A primary object of the present invention is to provide a method of manufacturing a flash memory device, so that hot carriers are generated closer to junctions of drains in a semiconductor substrate to thereby enable enhanced hot carrier injection efficiency, which in turn reduces the drain voltage to improve the short channel effects (SCE).

To achieve the above and other objects, the method of manufacturing a flash memory device according to the present invention includes the following steps: providing a semiconductor substrate; forming two gate structures on the semiconductor substrate; performing a source region ion implantation process to form two first source regions in the semiconductor substrate at two lateral outer sides of the two gate structures, and further performing an ion implantation process to form a lightly-doped first drain region in the semiconductor substrate between the two gate structures, wherein the first source regions and the first drain region have different doping concentration; performing a pocket implantation process to form two doped regions in the semiconductor substrate between the two gate structures and at two opposite sides of the first drain region; forming two facing L-shaped spacer walls between the two gate structures above the first drain region; depositing an oxide layer on the two L-shaped spacer walls; etching the oxide layer until the top surface of the first drain region; forming a salicide layer on a top surface of each of the two gate structures and the first drain region; performing an ion implantation process to form a second drain region beneath the first drain region, wherein the first and the second drain region having a steep junction profile compared to the first source regions; and forming a barrier plug above the first drain region.

With the flash memory device manufacturing method of the present invention, the drain voltage can be lowered, and the short channel effects can be improved through the pocket implantation process.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIGS. 1 to 9 are schematic sectional views of a flash memory device at different stages in a method of manufacturing a flash memory according to the present invention.

### DETAILED DESCRIPTION OF THE PREFERRED EMBODIMENTS

The present invention will now be described with a preferred embodiment thereof. For the purpose of easy to understand, elements that are the same in the illustrated preferred embodiment and the accompanying drawings are denoted by the same reference numerals.

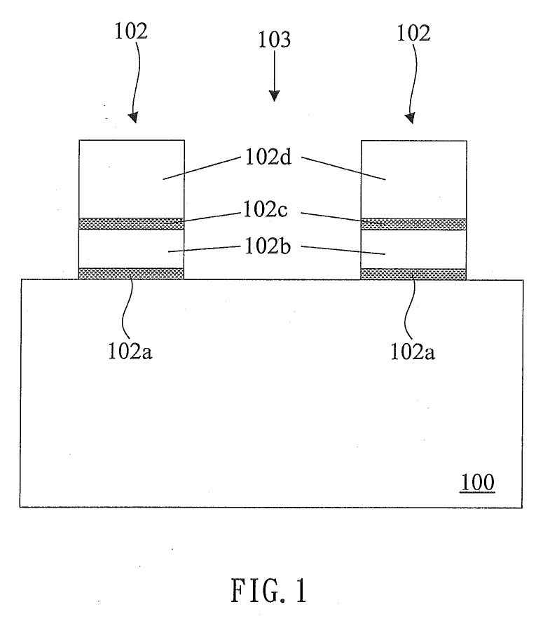

Please refer to FIGS. 1 to 9 that are schematic sectional views of a flash memory device at different stages in a method of manufacturing a flash memory device according to a preferred embodiment of the present invention. In FIG. 1, there is provided a semiconductor substrate 100, on which two gate structures 102 are formed. Each of the gate structures 102 includes a tunneling oxide layer 102a, a floating gate 102b, a dielectric layer 102c, and a control gate 102d. A channel 103 is also formed on the semiconductor substrate 100 between the two gate structures 102. The material for the semiconductor substrate 100 can be silicon, silicon-germanium (SiGe), silicon on insulator (SOI), silicon germanium on insulator (SGOI), or germanium on insulator (GOI). In the illustrated embodiments of the present invention, the semiconductor substrate 100 is a silicon substrate.

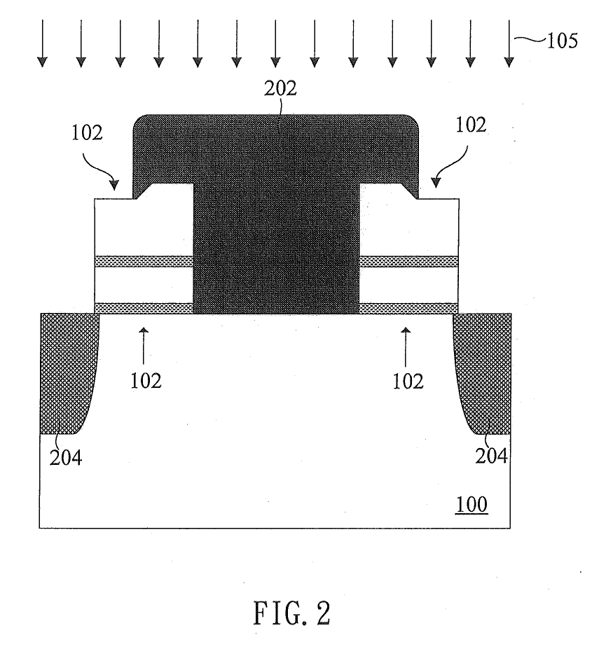

Please refer to FIG. 2. A mask 202 is formed on the semiconductor substrate 100, and the channel 103 between the two gate structures 102 is covered by the mask 202. Then, an ion implantation process 105 for forming source regions is performed to form two first source regions 204 in the semiconductor substrate 100 at two lateral outer sides of the two gate structures 102. In the case a P-type substrate is used for forming the flash memory device, arsenic (As) ions are used in the ion implantation process 105 for forming source regions at an implant dose of about 1×10⁻¹⁴˜8×10¹⁵ ion/cm² and with an implant energy of about 10˜70 KeV.

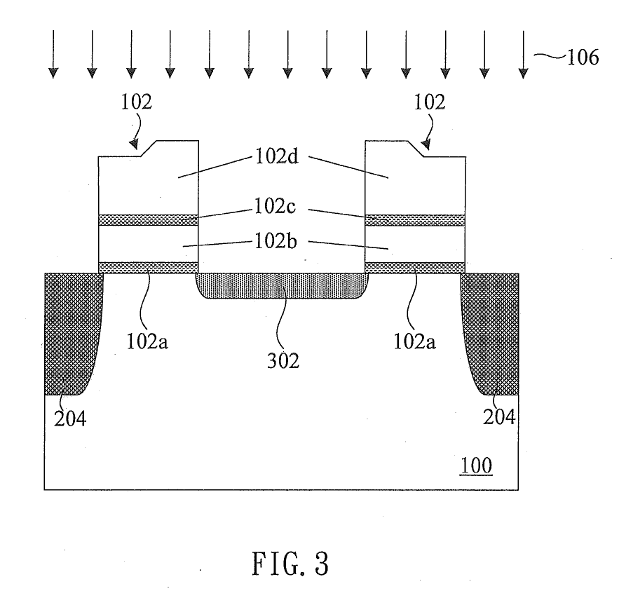

Then, as shown in FIG. 3, an ion implantation process 106 is performed, so that a first drain region 302 is formed in the semiconductor substrate 100 between the two gate structures 102 through lightly doped drain (LDD) implantation. The first source regions 204 are not symmetric with respect to the first drain region 302. In the case a P-type substrate is used for forming the flash memory device, arsenic (As) ions are used in the ion implantation process 106 at an implant dose of about 1×10¹⁴˜8×10¹⁵ ion/cm² and with an implant energy of about 10˜30 KeV.

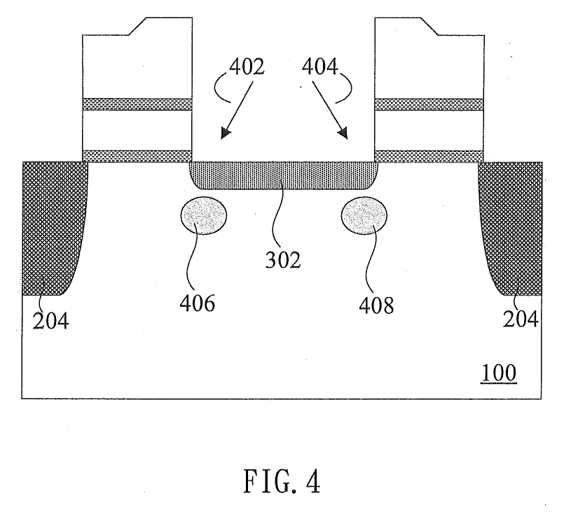

Please refer to FIG. 4. Thereafter, a pocket implantation process 402 is performed to form a first doped region 406 at one side of the first drain region 302. Then, a further pocket implantation process 404 is performed to form a second doped region 408 at another side of the first drain region 302 opposite to the first doped region 406. While the pocket implantation process 402 and the pocket implantation process 404 use different ion incident angles, all other ion implantation parameters are generally the same. The ion incident angle with respect to the semiconductor substrate 100 is ranged from about 15° to about 60°. The pocket implantation processes 402, 404 are able to restrict ions from lateral diffusion in an ion plantation process 606 for forming drain later. In the case a p-type substrate is used for forming the flash memory device, boron (B) ions or BF₂ ions are used in the pocket implantation processes 402, 404 at an implant dose of about 5×10¹²˜5×10¹⁴ ion/cm² and with an implant energy of about 10˜60 KeV.

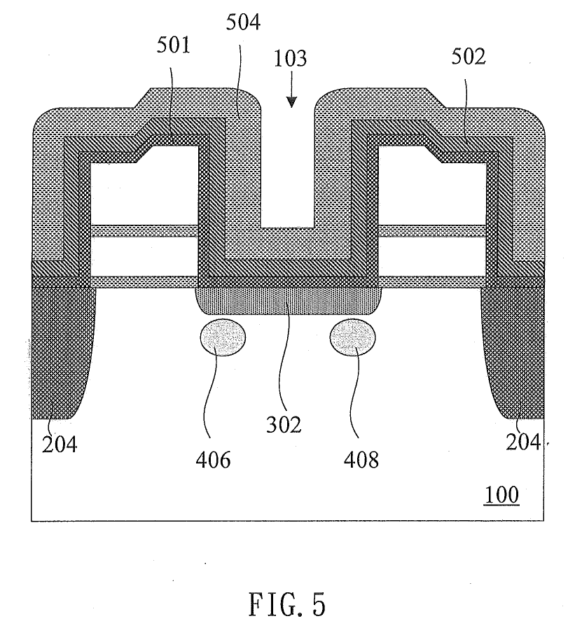

In FIG. 5, a first oxide wall 501 and a second silicon nitride (Si₃N₄) layer 502 are formed. And then, an oxide layer 504 is deposited through a known deposition technique, such as chemical vapor deposition (CVD) process that uses NH₃ and SiH₄ as the source gases, rapid thermal chemical vapor deposition (RTCVD) process, or atomic layer deposition (ALD) process. The oxide layer 504 can have a deposition thickness ranged from 200 Å to 1500 Å. In the preferred embodiment of the present invention, the deposition thickness of the oxide layer 504 is 750 Å.

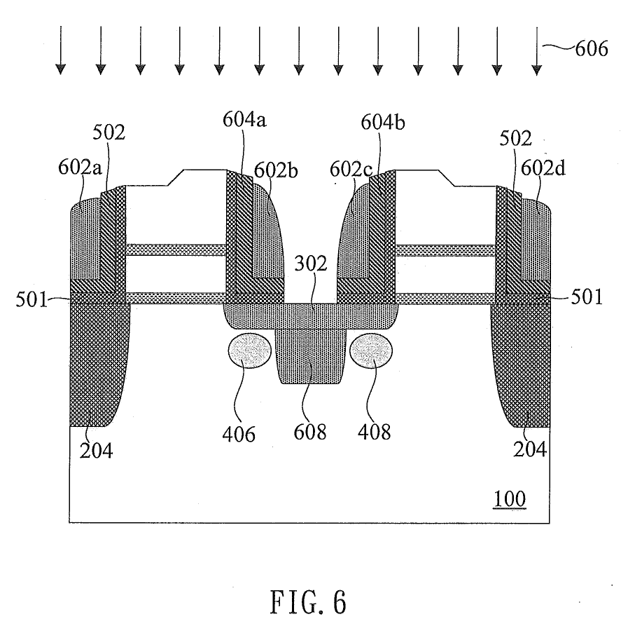

Please refer to FIGS. 5 and 6 at the same time. An etching process, such as dry etching or wet etching, is then performed, so that the oxide layer 504 is etched to form a plurality of oxide spacers 602a˜602d. Thereafter, a further etching process is performed, so that the second silicon nitride layer 502 is etched to form two facing L-shaped spacer walls 604a, 604b in the space region 103 between the two gate structures 102, and the first oxide wall 501 is also etched. Finally, an ion implantation process 606 for forming drain is performed to form a second drain region 608 beneath the first drain region 302. It is noted the first drain region 302 and the second drain region 608 each have a steep junction profile, which is different from a smooth junction profile of the source regions 204. Since the drain regions do not have a smooth junction profile like that of the source regions, hot carriers are generated closer to the junctions to thereby obtain enhanced hot carrier injection efficiency.

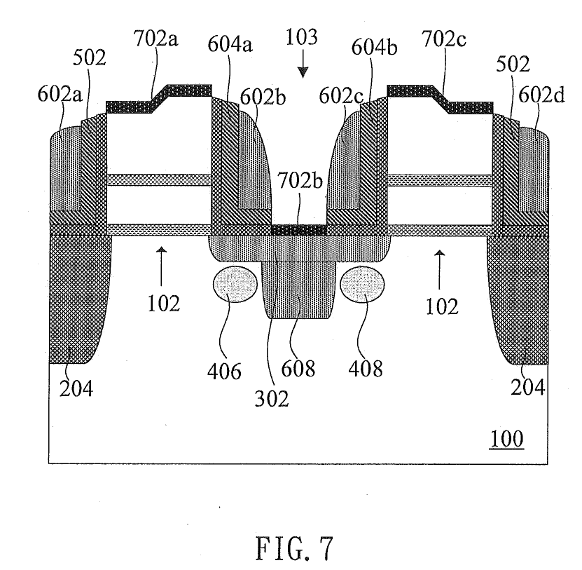

In FIG. 7, a metal silicide layer consisting of cobalt (Co), titanium (Ti), nickel (Ni), or molybdenum (Mo) is formed atop the device obtained in the above step as shown in FIG. 6, and a rapid thermal treatment process is performed, so that three salicide layers 702a, 702b, 702c are separately formed to reduce parasitic resistance and increase device driving force of the device.

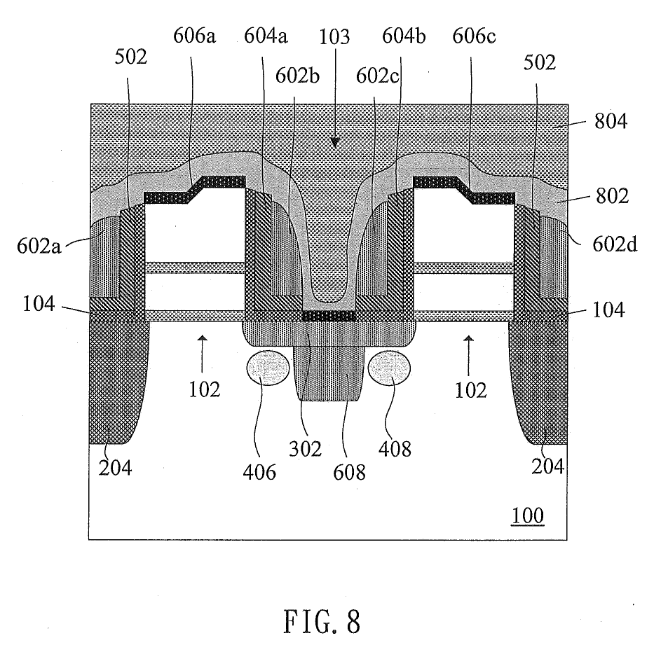

Please refer to FIG. 8. After the above-described steps, a contact etch stop layer (CESL) 802 is deposited on the semiconductor substrate 100. The CESL 802 can be SiN, silicon oxynitride, silicon oxide, etc. In the illustrated embodiments of the present invention, the CESL 802 is SiN. The CESL 802 has a deposition thickness ranged from 100 Å to 1500 Å. The stress translated from CESL to channel can be efficient by L-shaped SiN spacer due to proximity effect. Thus, the drain current can be enhanced. Thereafter, an inter-layer dielectric (ILD) layer 804, such as SiO₂, is deposited on the CESL 802.

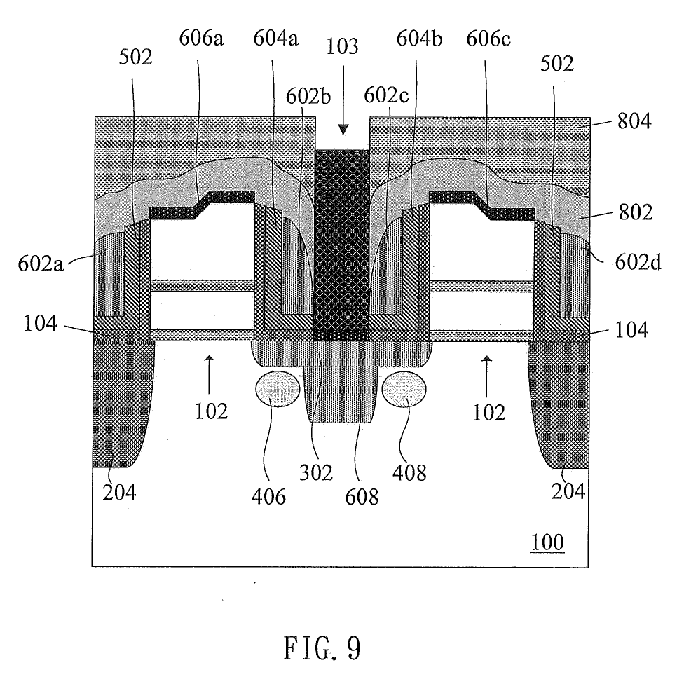

Finally, through a known photoresist and mask process, a contact hole 902 is formed in the space region 103 by anisotropic etching to extend from the inter-layer dielectric 804 to the CESL 802. Then, a barrier plug 904 is deposited in the contact hole 902 to form the flash memory device as shown in FIG. 9.

The present invention has been described with a preferred embodiment thereof and it is understood that the illustrated preferred embodiment is used only to describe part of the structure of a memory cell manufactured using the method of the present invention and is not intended to limit the scope of the present invention. It is also understood many changes and modifications in the described embodiment can be carried out without departing from the scope and the spirit of the invention that is intended to be limited only by the appended claims.

What is claimed is:

1. A method of manufacturing a flash memory device, comprising the following steps:
providing a semiconductor substrate;
forming two gate structures on the semiconductor substrate;
performing an ion implantation process to form two first source regions in the semiconductor substrate at two lateral outer sides of the two gate structures; and performing a further ion implantation process to form a lightly doped first drain region in the semiconductor substrate between the two gate structures; wherein the two first source regions and the first drain region have different doping concentration;
performing a pocket implantation process to form two doped regions in the semiconductor substrate between the two gate structures and at two opposite sides of the first drain region;
forming two facing L-shaped spacer walls between the two gate structures above the first drain region;
performing an ion implantation process to form a second drain region beneath the first drain region, wherein the first and the second drain region each have a steep junction profile compared to the first source regions; and
forming a barrier plug above the first drain region.

2. The method of manufacturing a flash memory device as claimed in claim 1, wherein the step of forming the L-shaped spacer walls between the two gate structures further comprising the following steps:
depositing an oxide layer on the two L-shaped spacer walls;
etching the oxide layer until the top surface of the first drain region; and
forming a salicide layer on a top surface of each of the two gate structures and the first drain region.
